(19) United States
(12) Patent Application Publication
(10) Pub. No.: US 2013/0256119 A1
(43) Pub. Date: Oct. 3, 2013

(54) METHOD FOR APPLYING POWER TO TARGET MATERIAL, POWER SUPPLY FOR TARGET MATERIAL, AND SEMICONDUCTOR PROCESSING APPARATUS

(71) Applicants: Bai Yang, Beijing (CN); Wei Xia, Beijing (CN)

(72) Inventors: Bai Yang, Beijing (CN); Wei Xia, Beijing (CN)

(73) Assignee: Beijing NMC Co., Ltd., Beijing (CN)

(21) Appl. No.: 13/378,936

(22) PCT Filed: Dec. 17, 2010
(86) PCT No.: PCT/CN2010/079951

§ 371 Date: Dec. 16, 2011

(30) Foreign Application Priority Data
Sep. 25, 2010 (CN) 201010291502

(51) Int. Cl. C23C 14/34

(52) U.S. Cl. CPC C23C 14/3485
USPC 204/192.12; 204/298.08

(57) ABSTRACT

A method for applying power to target material in a magnetron sputtering process is provided. The method includes: 10) connecting a main power supply and a maintaining power supply to the target material (2) respectively; 20) applying a particular main power in the form of pulses to the target material (2) by the main power supply; applying a particular maintaining power which is smaller than the main power to the target material (2) by the maintaining power supply at least during the pulse interval time (t2) of the main power supply, so as to maintain a glow discharge procedure of the sputtering process during the purse interval time (t2) of the main power supply. The method for applying power to target material can obviously enhance the metal ionization rate while the process stability and controllability are guaranteed. A power supply for target material (8) which includes a main power module (81) and a maintaining power module (82), and a semiconductor processing apparatus using the method for applying power to target material or the power supply for target material are also provided.

### TECHNICAL FIELD

The present invention relates to a technical field of micro-electronics, particularly to a method for applying power to target material, a power supply for target material, as well as a semiconductor processing apparatus using the method for applying power to target material/the power supply for target material.

### BACKGROUND

In modern industry, the micro-electronics processing technology has obtained great achievement. Wherein, large scale integrated circuits (ICs) have been widely used in various fields of production and life of people. Meantime, manufacturing process and process apparatus for integrated circuits are continuously improved and updated in an amazing speed.

Magnetron sputtering is a key technology used for manufacturing an interconnection layer of metal such as copper/aluminum in an integrated circuit. In the process of magnetron sputtering, part of atoms of target material are sputtered out in ion state from a surface of the target material. Commonly, a ratio of the metal particles going off in ion state from the target material to all the metal particles sputtered out is defined as ionization rate of the metal atoms. Since the control of energy and movement of metal ions is much easier compared with that of metal atoms, and can obtain a desired deposit effect more easily especially when some apertures and channels with larger aspect ratio are filled, therefore, the magnetron sputtering technology has become an essential and important processing means in the manufacturing process of integrated circuits. It could be forecasted that persons skilled in the art will face more and more newer and harder challenges as the degree of integrity improves highly and the feature dimension decreases continually.

Referring to FIG. 1, which is a schematic diagram of the principle of a commonly used magnetron sputtering apparatus. As shown in the figure, the magnetron sputtering apparatus includes a process chamber 1, target material 2 and a magnetron tube 3 which are arranged on the top of the process chamber 1, a DC (direct current) power supply 4 applying power to the target material 2, a substrate holding device 5 arranged on the bottom inside the process chamber 1, and a bottom electrode power supply 6 connected to the substrate holding device 5 so that the substrate holding device 5 also functions as a bottom electrode. A procedure for a copper interconnection process using the apparatus is as follows: first, a substrate 7 is fixed on the upper surface of the substrate holding device 5; then, argon gas is introduced into the process chamber 1, while the DC power supply 4 applies DC power to the target material so as to activate the argon gas to be plasma; argon ions with high energy in the plasma bombard the surface of the target material 2 so that particles of the target material 2 could get off; under the action of voltage bias of the bottom electrode, the particles of the target material, which are sputtered out, deposit on the surface of the substrate 7. During the above procedure, when the target material 2 is the metal material of copper, silver, gold and so on, a part of ionized metal particles would bombard the target material 2 due to the attraction of the negative voltage bias on the target material 2. When the metal ionization rate of the target material reaches a particular degree, it may be stopped to introduce the argon gas into the process chamber 1, and the glow discharge procedure of the sputtering process is maintained by the bombarding action of the sputtered metal ions on the target material. Such a phenomenon is called sustained self sputtering in the art. Since argon gas only needs to be introduced into the process chamber 1 at the build-up of a luminance start phase (a phase stimulating the process gas into plasma) during such a sustained self sputtering procedure while argon gas does not take part in the main sputtering process, the influence of argon atom or ion on the direction of the metal ion deposition may thus be avoided. Thus, such a sustained self sputtering process is widely used in copper interconnection process of integrated circuits.

Referring to FIG. 2, which is an experience data plot of metal ionization rate obtained by a copper sputtering experience applying the apparatus of FIG. 1. In the figure, fitted lines 1 and 2 represent magnetic field intensities of two commonly used magnetron tubes respectively, and are referred to as magnetic field intensity 1 and magnetic field intensity 2 respectively. The magnetic field intensity 2 is about two times the magnetic field intensity 1. As shown in the figure, when the magnetron tube has the magnetic field intensity 1, metal ionization rates of about 16%, 30% and 50% are obtained at applied DC power of 20 KW, 40 KW and 60 KW respectively. When the magnetron tube has the magnetic field intensity 2, metal ionization rates of about 20%, 50% and 70% are obtained at the above applied DC power of the magnetron tube 3 respectively. It can be known from the above data that the metal ionization rate of copper is proportional to the magnetic field intensity of the magnetron tube and the power density of power supply for the target material in a particular range. Herein, so-called power density is referred to as DC sputtering power of unit area of magnet sputtering slot. Thus, two methods could be applied to enhance the metal ionization rate during the sputtering process that is increasing the magnetic field intensity or the DC power of unit area of the target material.

However, magnetic field intensity of any material has a particular physical limit, thus, the method of enhancing the metal ionization rate by increasing the magnetic field intensity is limited. On the other hand, the amount of heat that the target material emits will rapidly increase if a high DC power is applied for too long, thus the heat stability and the process reliability of the apparatus are influenced. Moreover, continually applying a high magnetic field intensity and a high DC power will result in a problem that a depositing speed of material is too fast, while too fast depositing speed will increase the difficulty to control result of a deposition process, and thus result in a disadvantageous process result. Therefore, in practice of industrialized application, two parameter solutions of 60 KW DC power in combination with the magnetic field intensity 1 and 40 KW DC power in combination with the magnetic field intensity 2 are always applied, and a metal ionization rate of about 40% to 50% is achieved in practice. But, a process accuracy of 32 nm scale is realized by some high-tech companies, thus it can be seen that, in the near future, micro-electronics processing industry will enter into a new time of 32 nm soon. In order to realize such a new technology node, it is required that the metal ionization rate should reach 80% or more during a copper interconnection sputtering process, under a condition of guaranteeing the process stability and controllability. However, such requirement could not be satisfied in view of the technology and apparatus in the art.

### SUMMARY OF THE INVENTION

In order to solve the above problems, the present invention provides a method for applying power to target material, which can enhance the metal ionization rate of a sputtering process effectively while guaranteeing stability and controllability of the process, thus the requirement of a new technology node is satisfied.

Moreover, the present invention also provides a power supply for target material, which also can enhance the metal ionization rate of a sputtering process while guaranteeing stability and controllability of the process.

Further, the present invention also provides a semiconductor processing apparatus adopting such a method for applying power to target material/the power supply for target material, which also can enhance the metal ionization rate of a sputtering process while guaranteeing stability and controllability of the process.

In view of above, the present invention provides a method for applying power to target material for applying power to the target material during a magnetron sputtering process, comprising: 10) connecting a main power supply and a maintaining power supply to the target material respectively; 20) applying a particular main power in the form of pulses to the target material by the main power supply, wherein the active time of a single pulse is t1, and the pulse interval time is t2; applying a particular maintaining power to the target material by the maintaining power supply at least during the pulse interval time t2 of the main power supply, wherein the maintaining power is smaller than the main power, and is used to maintain a glow discharge procedure of the sputtering process during the time t2.

Wherein in the step 20), the main power is in a range of 80 kW-200 kW; pulse frequency f of the main power supply is in a range of 50 Hz-20 kHz; the time t1 is in a range of 5 μs-10 ms, wherein t1+t2=1/f and t1≦t2.

Wherein in the step 20), the maintaining power supply includes a pulsed DC power supply; output power of the pulsed DC power supply is in a range of 500 W-25 kW, pulse frequency of the pulsed DC power supply is equal to the pulse frequency of the main power supply, and pulse applying time of the pulsed DC power supply is corresponding to the pulse interval time t2 of the main power supply, so that the pulsed DC power supply and the main power supply alternatively apply power to the target material.

Wherein in the step 20), the maintaining power supply includes a DC power supply; output power of the DC power supply is in a range of 500 W-20 kW, and the DC power supply continually applies power to the target material.

Moreover, the present invention also provides a power supply for target material, which includes a main power module and a maintaining power module which are connected to the target material. The main power module applies a particular main power in the form of pulses to the target material, wherein the active time of a singe pulse is t1, and the pulse interval time is t2; the maintaining power module applies a particular maintaining power to the target material at least during the pulse interval time t2 of the main power module, wherein the maintaining power is smaller than the main power, and used to maintain a glow discharge procedure of the sputtering process during the time t2.

Wherein the main power module includes a pulsed DC power supply, the main power is in a range of 80 kW-200 kW; pulse frequency f of the main power supply is in a range of 50 Hz-20 kHz; the time t1 is in a range of 5 μs-10 ms, wherein t1+t2=1/f and t1≦t2.

Wherein the maintaining power module includes a pulsed DC power supply; output power of the pulsed DC power supply is in a range of 500 W-25 kW, pulse frequency of the pulsed DC power supply is equal to the pulse frequency of the main power supply, and pulse applying time of the pulsed DC power supply is corresponding to the pulse interval time t2 of the main power supply, so that the pulsed DC power supply and the main power supply alternatively apply power to the target material.

Wherein the maintaining power module includes a DC power supply; output power of the DC power supply is in a range of 500 W-20 kW, and the DC power supply continually applies power to the target material.

Further, the present invention also provides a semiconductor processing apparatus, comprising a process chamber, during a magnetron sputtering process in the process chamber, the above mentioned method for applying power to target material provided by the present invention is adopted to apply power to the target material.

Furthermore, the present invention also provides a semiconductor processing apparatus, comprising a process chamber, during a magnetron sputtering process in the process chamber, the target material is connected to the above mentioned power supply for target material provided by the present invention to apply power to the target material.

The advantages of the present invention are as follows:

The method for applying power to target material provided by the present invention first connects a main power supply and a maintaining power supply to the target material respectively; and then applies a particular main power in the form of pulses to the target material by the main power supply and applies a particular maintaining power which is smaller than the main power to the target material by the maintaining power supply at least during the pulse interval time of the main power supply, so as to maintain a glow discharge procedure of the sputtering process during the pulse interval time. In view of above, during the above process of applying power, the application of the main power in the form of pulses can effectively avoid the problem, that the amount of heat the target material emits would rapidly increase, due to the fact that high power is continually applied, moreover it can make the momentary metal ionization rate reach 80% or more when the applied main power is high enough, thus satisfying requirements of the new technology node and making the sputtering process level reach requirements of 32 nm scale. Further, the method for applying power to target material provided by the present invention applies a maintaining power, which is smaller than the main power and can maintain a glow discharge procedure of the sputtering process, to the target material during the pulse interval time of the main power supply. Since the maintaining power is relatively low, the speed of sputtering deposit could be kept at a level to be controlled easily, while the continuity of process is maintained, thus it helps to obtain a reliable and stable process result. In summary, the method for applying power to target material provided by the present invention can obviously enhance the metal ionization rate of sputtering process in case that the process stability and controllability are guaranteed, thus the requirement of new technology node is satisfied.

Further, the power supply for target material provided by the present invention includes a main power module and a maintaining power module which are connected to the target material. Wherein, the main power module could apply a particular main power in the form of pulses to the target material, while the maintaining power module could apply a particular maintaining power smaller than the main power to the target material during the pulse interval time of the main power module, so as to maintain a glow discharge procedure of the sputtering process during the interval time of the main power. In view of above, with the power supply for target material according to the present invention, since the main power module of the power supply for target material applies the main power in the form of pulses to the target material, the problem, that the amount of heat that the target material emits would rapidly increase, due to the fact that the high power is continually applied, can be effectively avoided, moreover, the metal ionization rate can be made to reach 80% or more when the applied main power supply is high enough, thus satisfying requirements of new technology node and making the sputtering process level reach the requirement of 32 nm scale. Further, the power supply for target material provided by the present invention applies a maintaining power, which is smaller than the main power and can maintain a glow discharge procedure of the sputtering process, to the target material during the pulse interval time of the main power supply by means of the maintaining power module. Since the maintaining power is relatively low, the speed of sputtering deposit could be kept at a level to be controlled easily, while the continuity of process is maintained, thus it helps to obtain a stable and reliable process result. In summary, the power supply for target material provided by the present invention can effectively enhance the metal ionization rate of sputtering process in case that the process stability and controllability are guaranteed, thus the requirement of new technology node is satisfied.

As another technical solution, the semiconductor processing apparatus provided by the present invention adopts the above method for applying power to target material provided by the present invention or connects the power supply for target material provided by the present invention to the target material during a magnetron sputtering process, and it can effectively enhance the metal ionization rate of sputtering process in case that the process stability and controllability are guaranteed, thus the requirement of new technology node is satisfied.

### BRIEF DESCRIPTION OF THE DRAWINGS

FIG. 1 is a schematic diagram of principle of a commonly used magnetron sputtering apparatus;

FIG. 2 is an experience data plot of metal ionization rate obtained by a copper sputtering experience applying the apparatus of FIG. 1;

FIG. 3 is a flow chart of a method for applying power to target material provided by the present invention;

FIG. 4 is a schematic diagram of power applied in a first specific embodiment of the method for applying power to target material provided by the present invention;

FIG. 5 is a schematic diagram of power applied in a second specific embodiment of the method for applying power to target material provided by the present invention; and

FIG. 6 is a schematic diagram of structure of a specific embodiment of a semiconductor processing apparatus provided by the present invention.

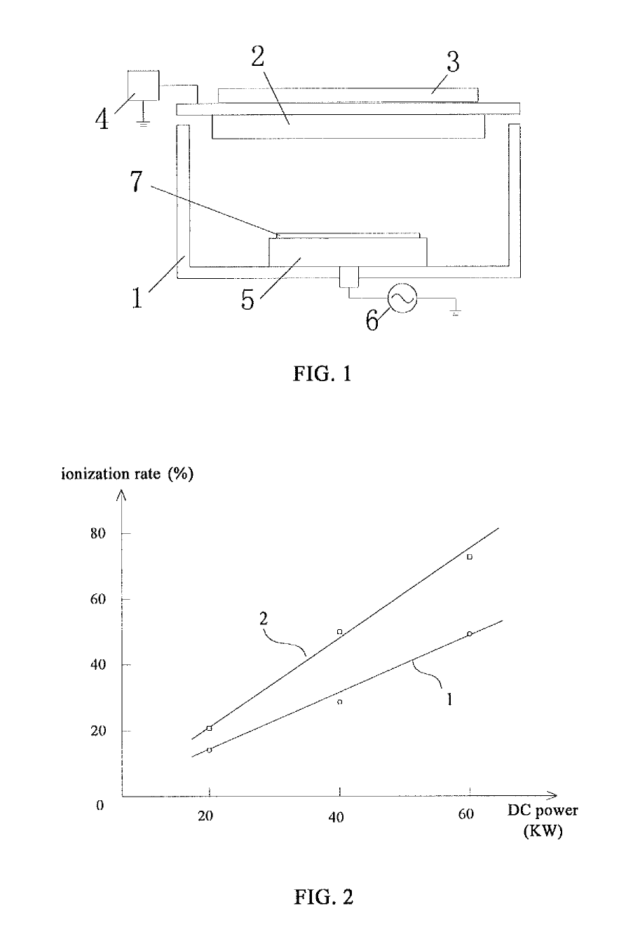

### DETAILED DESCRIPTION

For better understanding of the technical solution of the present invention by the persons skilled in the art, a method for applying power to target material, a power supply for target material, as well as a semiconductor processing apparatus adopting the above method for applying power to target material/power supply for target material provided by the present invention will be described in detail by reference to the drawings.

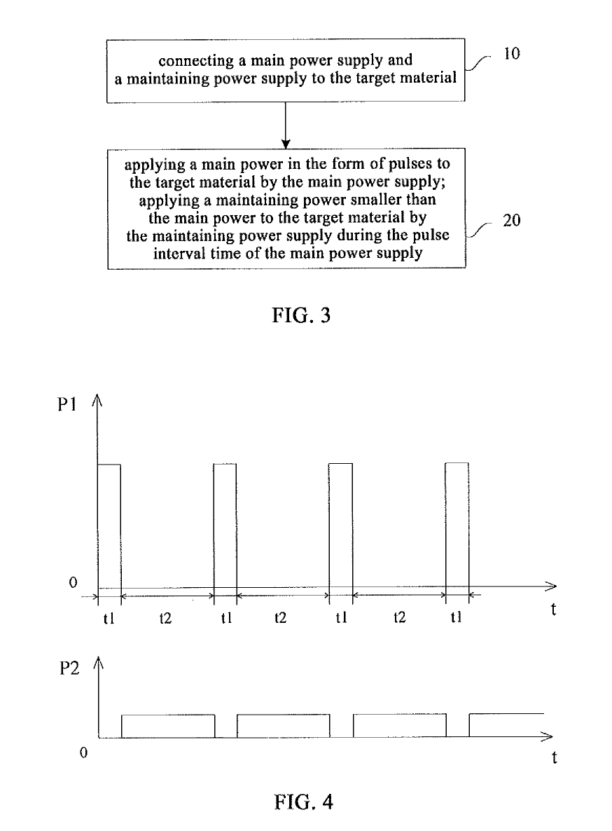

FIG. 3 is a flow chart of a method for applying power to target material provided by the present invention. The method for applying power to target material is mainly used for applying power to the target material during a magnetron sputtering process, and includes the following steps: 10) connecting a main power supply and a maintaining power supply to the target material respectively; 20) applying a particular main power in the form of pulses to the target material by the main power supply, wherein the active time of a singe pulse is t1, and the pulse interval time is t2, and the metal ionization rate can be made to reach 80% or more when the applied main power is high enough; applying a particular maintaining power to the target material by the maintaining power supply at least during the pulse interval time t2 of the main power supply, wherein the maintaining power is smaller than the main power, and the maintaining power is used to maintain a glow discharge procedure of the sputtering process during the time t2.

Specifically, the main power supply includes a pulsed DC power supply, wherein the pulse active time is t1, the pulse frequency is f, and the pulse period is T=1/f=t1+t2. Output power of the main power supply is in a range of 80 kW-200 kW, and the function of the main power supply makes the metal ionization rate of the target material increase instantly (the ideal value is at a level of 80% or more) during a magnetron sputtering process, so as to satisfy the process requirements of 32 nm technology node. Moreover, since the main power is output from the main power supply to the target material in the form of pulses, the problem, that the temperature of the target material would suddenly increase, due to the fact that high DC power is applied for a long time, is avoided. Based on the same consideration, in practice of operation, it is generally required that the active time t1 of pulse of the main power should be smaller than or equal to the pulse interval time t2 thereof, i.e. t1≦t2. Since the length of the pulse active time t1 will determine the metal ionization rate of the whole process and an average deposition speed of the magnetron sputtering process, the value of t1 is selected from a particular range according to the requirement of a process in practice, and in general, t1 is in a range of 5 μs-10 ms.

The maintaining power in above step 20) may use the same pulsed DC power supply as the above main power supply, and it could also use a DC power supply. That's to say, the maintaining power supply may apply the maintaining power to the target material only during the pulse interval time of the main power supply, or continuously apply the maintaining power to the target material, as long as the target material can get a particular maintaining power during the pulse interval time t2 of the main power supply so as to maintain a plasma glow discharge procedure of the sputtering process. In practice, when a pulsed DC power supply is used as the maintaining power supply, the value of the maintaining power is in a range of 500 W-25 kW; when a DC power supply is used as the maintaining power supply, the value of the maintaining power is in a range of 500 W-20 kW. The specific implementing procedure of the step 20) may refer to the following two specific embodiments.

FIG. 4 is a schematic diagram of power applied in a first specific embodiment of the method for applying power to target material. In the figure, the lateral axis represents the power applying time t, and the longitudinal axis represents the applied power P, wherein P1 represents the main power, and P2 represents the maintaining power. In the embodiment, the maintaining power use a pulsed DC power supply having the same pulse frequency as that of the above main power supply. The pulse frequency of the pulsed DC power supply is the same as that of the above main power supply, while the pulse active time is complementary to the active time of the main power supply, i.e. the pulse interval time t2 of the main power supply is the pulse active time of the maintaining power supply, while the pulse active time t1 of the main power supply is the pulse interval time of the maintaining power supply, so that the maintaining power and the main power are alternatively applied to the target material. In this way, a power is supplied to the target material at any time, so that the continuity of the magnetron sputtering process is kept.

In the embodiment, specific parameters of power and time are as follows: the pulse frequency f of the maintaining power supply and the maintaining power supply is 10 kHz, i.e. the pulse period is 100 ms; the main power P1 is set to be 120 kW, and the pulse active time t1 is 10 ms; the maintaining power P2 is 5 kW, and the pulse active time t2 is 90 ms. As shown in FIG. 4, during the sputtering process, the main power P1 is first applied and kept for the pulse active time t1; and while a discharge procedure of plasma is finished, the metal ionization rate is obviously enhanced (the ideal value is at a level of 80% or more); then, the maintaining power P2 is applied and kept for the pulse active time t2, so as to maintain a glow discharge procedure of the plasma; the procedure of alternative applying of the main power P1 and the maintaining power P2 is repeated until the process ends. In this embodiment, during the whole sputtering process, the average power applied to the target material is 16.5 W, thus, not only a high metal ionization rate is achieved, but also the sputtering deposition speed is kept in a range of easily controlling, thus process requirements of 32 nm technology node are satisfied.

It should be noted that, values of the main power, the maintaining power, pulse frequency, t1, and t2 etc. applied in the embodiment are values selected for illustrating the specific implementing procedure of method of the present invention conveniently. The present invention is not limited to these values, and could select within allowable ranges according to process requirements.

From above, it can be known that the method for applying power to target material provided by the embodiment uses two pulsed DC power supplies to alternatively apply power to the target material. Wherein, one pulsed DC power supply is used as a main power supply which applies a higher power (80 kW-200 kW) to the target material in a shorter time; so that the metal ionization rate is increased to 80% or more so as to avoid the problem, that the amount of heat the target material emits would rapidly increase, due to the fact that high power is applied for a long time, while the process requirements of 32 nm technology node are satisfied. The other pulsed DC power supply is used as a maintaining power supply which applies a lower power (500 W-25 kW) to the target material in a longer time; so that the deposition speed of the process is stable while a glow discharge procedure of the plasma is maintained, so as to keep the deposition speed of the whole process in a controllable range, thus it helps to obtain a reliable and stable process result.

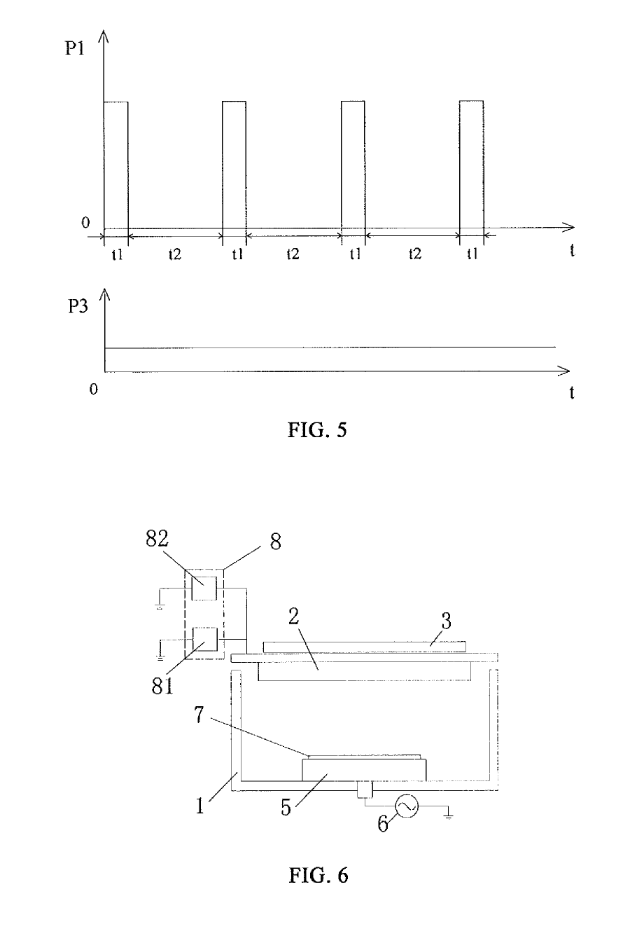

FIG. 5 is a schematic diagram of power adopted in a second specific embodiment of the method for applying power to target material. In the figure, the lateral axis represents power applying time t, and the longitudinal axis represents applied power P, wherein P1 represents the main power, and P3 represents the maintaining power. The difference between this embodiment and the above first embodiment of the method for applying power to target material is that the maintaining power supply uses a DC power supply; that's to say, the maintaining power supply applies continually power to the target material during the whole process. From above, it can be known that during the pulse active time t1 of the main power supply, a superposed power of the main power P1 and the maintaining power P3 is applied to the target material; at this moment, a high metal ionization rate (80% or more) is obtained. During the pulse interval time t2 of the main power supply, power is applied to the target material only by the maintaining power P3, so as to maintain a glow discharge procedure. The above procedures are repeated until the process ends. It is easy to understand that, the advantage effect of the above first embodiment could also be obtained by this embodiment, that is, a very high metal ionization rate is obtained while heat that the target material emits and the deposition speed are effectively controlled, thus the process requirements of new technology node are satisfied.

It should be noted that, in the method for applying power to target material provided by the present invention, the manner of applying maintaining power is not limited to the above embodiments. First of all, when the maintaining power supply is a pulsed DC power supply, the pulse applying time of such a pulsed DC power supply could be longer than the pulse interval time of the main power supply; that's to say, such a pulsed DC power supply starts to be applied at a timing before the end of pulse applying time of the main power supply, and/or such a pulsed DC power supply is applied until a timing after the next pulse applying time of the main power supply starts. Secondly, when the maintaining power supply is a DC power supply, the maintaining power could be applied to the target material in an interrupted form only at the interval time of the main power supply in the manner of controlling the on/off of the DC power supply.

As another technical solution, the present invention also provides a power supply for target material, for applying power to target material during a magnetron sputtering process. The power supply for target material comprises a main power module and a maintaining power module connected to the target material. During the magnetron sputtering process, the main power module applies a particular main power (which is high enough to make the metal ionization rate reach 80% or more) in the form of pulses to the target material, wherein the active time of a singe pulse is t1, and the pulse interval time is t2. The maintaining power module applies a particular maintaining power to the target material at least during the pulse interval time t2 of the main power module, wherein the maintaining power is obviously smaller than the main power, and the maintaining power is used to maintain a glow discharge procedure of the sputtering process during the time t2.

Specifically, the main power module includes a pulsed DC power supply, the output power range of the pulsed DC power supply is in a range of 80 kW-200 kW, pulse frequency f of the pulsed DC power supply is in a range of 50 Hz-20 kHz, the pulse active time t1 of a single pulse is in a range of 5 μs-10 ms, wherein conditions t1+t2=1/f and t1≦t2 are satisfied.

In a specific embodiment of the power supply for target material, the maintaining power module uses a pulsed DC power supply, output power of the pulsed DC power supply is in a range of 500 W-25 kW, pulse frequency of the pulsed DC power supply is equal to the pulse frequency of the main power supply, and the pulsed DC power supply and the main power supply alternatively apply power to the target material.

In another specific embodiment of the power supply for target material, the maintaining power module uses a DC power supply, and output power of the DC power supply is in a range of 500 W-20 kW.

The specific process of applying power to the target material in the sputtering process is omitted since it is similar to or the same as the above method for applying power to target material of the present invention.

The above power supply for target material provided by the present invention applies alternatively variant power to the target material by means of a main power module and a maintaining power module. On one hand, the main power module applies a high power (80 kW-200 kW) to the target material in the form of pulses; so that the metal ionization rate is suddenly increased to 80% or more, so as to avoid the problem, that the target material would emit heat intensely, due to the fact that high power is applied for a long time, while the process requirements of a new technology node are satisfied. On the other hand, the maintaining power module applies a lower power (500 W-25 kW or 500 W-20 kW) to the target material at the pulse interval time of the main power module, so that the deposition speed of the process is stable while a glow discharge procedure of plasma is maintained, so as to keep the deposition speed of the whole process in a controllable range, thus it helps to obtain a reliable and stable process result.

As another technical solution, the present invention also provides a semiconductor processing apparatus which adopts the above power supply for target material provided by the present invention.

Referring to the FIG. 6, which is a schematic diagram of structure of a specific embodiment of a semiconductor processing apparatus provided by the present invention. The semiconductor processing apparatus includes a process chamber 1, a substrate holding device 5 arranged on the bottom inside the process chamber 1, target material 2 and a magnetron tube 3 which are arranged in the upper part of the process chamber 1. A bottom electrode power supply 6 is connected to the substrate holding device 5 so that the substrate holding device 5 also function as a bottom electrode during the process. The target material 2 is connected to the power supply for target material 8 provided by the present invention. The power supply for target material 8 comprises a main power module 81 and a maintaining power module 82. The main power module 81 and the maintaining power module 82 apply power to the target material during the process, so as to increase the metal ionization rate while ensuring the stability and controllability of the process, thus satisfying process requirements of new technology node. The specific process of applying power to the target material is omitted since it is the same as or similar to applying process of the above method for applying power to target material and/or power supply for target material provided by the present invention.

Further, the present invention also provides a semiconductor processing apparatus which adopts the above method for applying power to target material provided by the present invention; and it could also enhance the metal ionization rate while ensuring the stability and controllability of the process, thus satisfying the process requirements of new technology node.

It should be understood that the description of the embodiments above is only for the purpose of helping to understand the principle of the present invention. For the persons skilled in the art, many improvements and modifications may be applied to the present invention without departing from the spirit and theory of the present invention. These improvements and modifications are also covered by the scope of the claims of the present invention.

1. A method for applying power to target material used for applying power to the target material during a magnetron sputtering process, comprising:
10) connecting a main power supply and a maintaining power supply to the target material respectively;
20) applying a particular main power in the form of pulses to the target material by the main power supply, wherein the active time of a singe pulse is t1, and the pulse interval time is t2; applying a particular maintaining power to the target material by the maintaining power supply at least during the pulse interval time t2 of the main power supply, wherein the maintaining power is smaller than the main power, and the maintaining power is used to maintain a glow discharge procedure of the sputtering process during the time t2.

2. The method for applying power to target material according to claim 1, wherein the main power is in a range of 80 kW-200 kW; pulse frequency f of the main power supply is in a range of 50 Hz-20 kHz; t1 is in a range of 5 μs-10 ms, wherein t1+t2=1/f and t1≦t2.

3. The method for applying power to target material according to claim 2, wherein, the maintaining power supply includes a pulsed DC power supply; output power of the pulsed DC power supply is in a range of 500 W-25 kW, pulse frequency of the pulsed DC power supply is equal to the pulse frequency of the main power supply, and pulse applying time of the pulsed DC power supply is corresponding to the pulse interval time t2 of the main power supply, so that the pulsed DC power supply and the main power supply alternatively apply power to the target material.

4. The method for applying power to target material according to claim 2, wherein the maintaining power supply includes a DC power supply; output power of the DC power supply is in a range of 500 W-20 kW, and the DC power supply continually applies power to the target material.

5. A power supply for target material, comprising: a main power module and a maintaining power module which are connected to the target material,
the main power module applies a particular main power in the form of pulses to the target material, wherein the active time of a singe pulse is t1, and the pulse interval time is t2;
the maintaining power module applies a particular maintaining power to the target material at least during the pulse interval time t2 of the main power module, wherein the maintaining power is smaller than the main power, and the maintaining power is used to maintain a glow discharge procedure of a sputtering process during the time t2.

6. The power supply for target material according to claim 5, wherein the main power module includes a pulsed DC power supply, the main power is in a range of 80 kW-200 kW; pulse frequency f of the main power supply is in a range of 50 Hz-20 kHz; t1 is in a range of 5 μs-10 ms, wherein t1+t2=1/f and t1≦t2.

7. The power supply for target material according to claim 6, wherein the maintaining power module includes a pulsed DC power supply; output power of the pulsed DC power supply is in a range of 500 W-25 kW, pulse frequency of the pulsed DC power supply is equal to the pulse frequency of the main power module, and pulse applying time of the pulsed DC power supply is corresponding to the pulse interval time t2 of the main power module, so that the pulsed DC power supply and the main power module alternatively apply power to the target material.

8. The power supply for target material according to claim 6, wherein characterized in that the maintaining power module includes a DC power supply; output power of the DC power supply is in a range of 500 W-20 kW, and the DC power supply continually applies power to the target material.

9. A semiconductor processing apparatus, comprising: a process chamber, and wherein during a magnetron sputtering-process in the process chamber, the method for applying power to target material is according to any one of claims 1-4 is adopted to apply power to the target material.

10. A semiconductor processing apparatus, comprising: a process chamber, wherein during a magnetron sputtering process in the process chamber, target material is connected to the power supply for target material according to any one of claims 5-8 for applying power to the target material.
